(19) United States
(12) Patent Application Publication
(10) Pub. No.: US 2014/0213015 A1
(43) Pub. Date: Jul. 31, 2014

(54) LASER PATTERNING PROCESS FOR BACK CONTACT THROUGH-HOLES FORMATION PROCESS FOR SOLAR CELL FABRICATION

(71) Applicants: Jeffrey L. Franklin, Albuquerque, NM (US); Yi Zheng, Sunnyvale, CA (US)

(72) Inventors: Jeffrey L. Franklin, Albuquerque, NM (US); Yi Zheng, Sunnyvale, CA (US)

(21) Appl. No.: 13/750,026

(22) Filed: Jan. 25, 2013

(51) Int. Cl. H01L 31/18

(52) U.S. Cl. CPC H01L 31/1864
USPC 438/89

(57) ABSTRACT

Embodiments of the invention contemplate formation of a high efficiency solar cell utilizing a laser patterning process to form openings in a passivation layer while maintaining good film properties of the passivation layer on a surface of a solar cell substrate. In one embodiment, a method of forming an opening in a passivation layer on a back surface of a solar cell substrate includes transferring a substrate having a passivation layer formed on a back surface of a substrate into a laser patterning apparatus, the substrate having a first type of doping atom on the back surface of the substrate and a second type of doping atom on a front surface of the substrate, providing laser radiation generated by the laser patterning apparatus from the front surface transmitting through the substrate to the passivation layer disposed on the back surface of the substrate, and forming openings in the passivation layer.

### BACKGROUND OF THE INVENTION

1. Field of the Invention

Embodiments of the invention generally relate to the fabrication of back contact through-holes in a passivation layer of photovoltaic cells, more particularly, fabrication of back contact through-holes in a passivation layer on a back surface of photovoltaic cells.

2. Description of the Related Art

Solar cells are photovoltaic devices that convert sunlight directly into electrical power. The most common solar cell material is silicon, which is in the form of single or multicrystalline substrates, sometimes referred to as wafers. Because the amortized cost of forming silicon-based solar cells to generate electricity is higher than the cost of generating electricity using traditional methods, there has been an effort to reduce the cost required to form solar cells.

There are various approaches for fabricating the active regions and the current carrying metal lines, or conductors, of the solar cells. Manufacturing high efficiency solar cells at low cost is the key for making solar cells more competitive for the generation of electricity for mass consumption. The efficiency of solar cells is directly related to the ability of a cell to collect charges generated from absorbed photons in the various layers. A good passivation layer can provide a desired film property that reduces recombination of the electrons or holes in the solar cells and redirects electrons and charges back into the solar cells to generate photocurrent. When electrons and holes recombine, the incident solar energy is re-emitted as heat or light, thereby lowering the conversion efficiency of the solar cells.

FIG. 1 depicts a cross sectional view of a conventional crystalline silicon type solar cell substrate, or substrate 110 that may have a passivation layer 104 formed on a surface, e.g. a back surface 125, of the substrate 110. A silicon solar cell 100 is fabricated on the crystalline silicon type solar cell substrate 110 having a textured surface 112. The substrate 110 includes a p-type base region 121, an n-type emitter 122, and a p-n junction region 123 disposed therebetween. The p-n junction region 123 is formed between the p-type base region 121 and the n-type emitter 122 to form a heterojunction type solar cell 100. The electrical current generates when light strikes a front surface 120 of the substrate 110. The generated electrical current flows through metal front contacts 108 and metal backside contacts 106 formed on the back surface 125 of the substrate 110.

A passivation layer 104 may be disposed between the back contact 106 and the p-type base region 121 on the back surface 125 of the solar cell 100. The passivation layer 104 may be a dielectric layer providing good interface properties that reduce the recombination of the electrons and holes, drives and/or diffuses electrons and charge carriers back to the junction region 123, and minimize light absorption. The passivation layer 104 is drilled and/or patterned to form openings 109 (e.g., back contact through-holes) that allow a portion 107, e.g., fingers, of the back contact 106 extending through the passivation layer 104 to be in electrical contact/communication with the p-type base region 121. The plurality of fingers 107 may be formed in the passivation layer 104 that are electrically connected to the back contact 106 to facilitate electrical flow between the back contact 106 and the p-type base region 121. Generally, the back contact 106 is formed in the passivation layer 104 by a metal paste process, pasting metal into the openings 109 formed in the passivation layer 104. However, when pasting the metal fingers 107 of the back contact 106 into the openings 109 formed in the passivation layer 104, the aggressive etchants contained in the metal paste may undesirably etch and attack the passivation layer 104 adjacent to the openings 109, thereby deteriorating the film properties of the passivation layer 104. FIG. 2 depicts an enlarged view 150 of the fingers 107 formed in the openings 109 of the passivation layer 104 disposed between the back contact 106 and the p-type base region 121. It is noted that the substrate 110 depicted in FIG. 2 is flipped over and up side down for ease of explanation of the openings 109 formed in the passivation layer 104. The etchant from the metal paste may attack the sidewalls 204 of the openings 109 formed in the passivation layer 104, forming undesired cracks, pits, or voids around the openings 109 in the passivation layer 104, thereby resulting metal paste leaking into undesired areas in the passivation layer 104 and eventually leading to circuit shortage or device failure.

Conventionally, a laser drilling process may be alternatively utilized to form openings in the passivation layer 104 for back contact interconnection. However, conventional laser drilling processes is utilized to form the openings 109 in the passivation layer 104 often have excessive laser energy which may not only drill the openings 109 in the passivation layer 104, but also undesirably damage the film properties of the passivation layer 104 adjacent to the opening 109, resulting in film peeling and poor interface adhesion.

Therefore, there exists a need for improved methods and apparatus to form openings in a passivation layer while maintaining good passivation layer film properties.

### SUMMARY OF THE INVENTION

Embodiments of the invention contemplate the formation of a high efficiency solar cell utilizing a laser patterning process to form openings in a passivation layer while maintaining good film properties of the passivation layer on a surface of a solar cell substrate. In one embodiment, a method of forming an opening in a passivation layer on a back surface of a solar cell substrate includes transferring a substrate having a passivation layer formed on a back surface of a substrate into a laser patterning apparatus, the substrate having a first type of doping atom on the back surface of the substrate and a second type of doping atom on a front surface of the substrate, providing laser radiation generated by the laser patterning apparatus from the front surface transmitting through the substrate to the passivation layer disposed on the back surface of the substrate, and forming openings in the passivation layer.

In another embodiment, a method of forming an opening in a passivation layer on a back surface of a solar cell substrate includes transferring a substrate having a passivation layer formed on a back surface of a substrate into a laser patterning apparatus, the substrate fabricated from a crystalline silicon material having a first type of doping atom on the back surface of the substrate and a second type of doping atom on a front surface of the substrate, providing laser radiation from the laser patterning apparatus to the passivation layer disposed on the back surface of the substrate, wherein the laser radiation is selected at a wavelength that has minimum absorption to the crystalline silicon material formed in the substrate, and forming openings in the passivation layer.

In yet another embodiment, a method of forming an opening in a passivation layer on a back surface of a solar cell substrate includes transferring a substrate having a passivation layer formed on a back surface of a substrate into a laser patterning apparatus, the substrate fabricating from a crystalline silicon material having a first type of doping atom on the back surface of the substrate and a second type of doping atom on a front surface of the substrate, providing laser radiation to the passivation layer disposed on the back surface of the substrate from the front surface of the substrate, and simultaneous forming openings in the passivation layer while thermal annealing a region of the front surface of the substrate where the laser radiation is passing therethrough.

### BRIEF DESCRIPTION OF THE DRAWINGS

So that the manner in which the above recited features of the present invention can be understood in detail, a more particular description of the invention, briefly summarized above, may be had by reference to embodiments, some of which are illustrated in the appended drawings.

FIG. 1 depicts a schematic cross-sectional view of a conventional solar cell having a passivation layer and back metal contact formed on a back surface of a substrate;

FIG. 2 depicts a enlarged partial sectional view of the passivation layer disposed on the substrate of FIG. 1;

FIG. 3 depicts a side view of one embodiment of a laser patterning apparatus that may be utilized to practice the present invention;

FIG. 4 depicts a flow diagram of a method for performing a laser patterning process on a passivation layer of a solar cell according to embodiments of the invention;

FIGS. 5A-5B depict a cross sectional view of a passivation layer formed on a substrate after a laser patterning process thereon in accordance with the method of FIG. 4;

FIG. 5C depicts a cross sectional view of a front metal connection layer formed on a top surface of a substrate after a laser patterning process thereon in accordance with the method of FIG. 4; and

FIG. 5D depicts a cross sectional view of a metal layer filing into a patterned passivation layer formed on a substrate after a laser patterning process thereon in accordance with the method of FIG. 4.

To facilitate understanding, identical reference numerals have been used, where possible, to designate identical elements that are common to the figures. It is contemplated that elements and features of one embodiment may be beneficially incorporated in other embodiments without further recitation.

It is to be noted, however, that the appended drawings illustrate only exemplary embodiments of this invention and are therefore not to be considered limiting of its scope, for the invention may admit to other equally effective embodiments.

### DETAILED DESCRIPTION

Embodiments of the invention contemplate the formation of through-holes in a passivation layer and back metal contact, filling in the through-holes, and maintaining high passivation layer film qualities so as to form a high efficiency solar cell device. In one embodiment, the method utilizes a laser patterning process to form through-holes (e.g., openings) in a passivation layer formed on a back surface of a solar cell substrate. The laser patterning process may provide a laser radiation from a front surface of the solar cell substrate to a predetermined spot in a passivation layer disposed on the back surface of the solar cell substrate to remove the passivation layer formed thereon. During processing, the energy level from the laser radiation passing through the substrate may also thermally anneal the film structures formed on the front surface of the solar cell substrate. The laser patterning process may form openings in the passivation layer on the back surface of the substrate while maintaining desired film properties of an interface formed adjacent to the openings in contact with the back metal contact later filled therein.

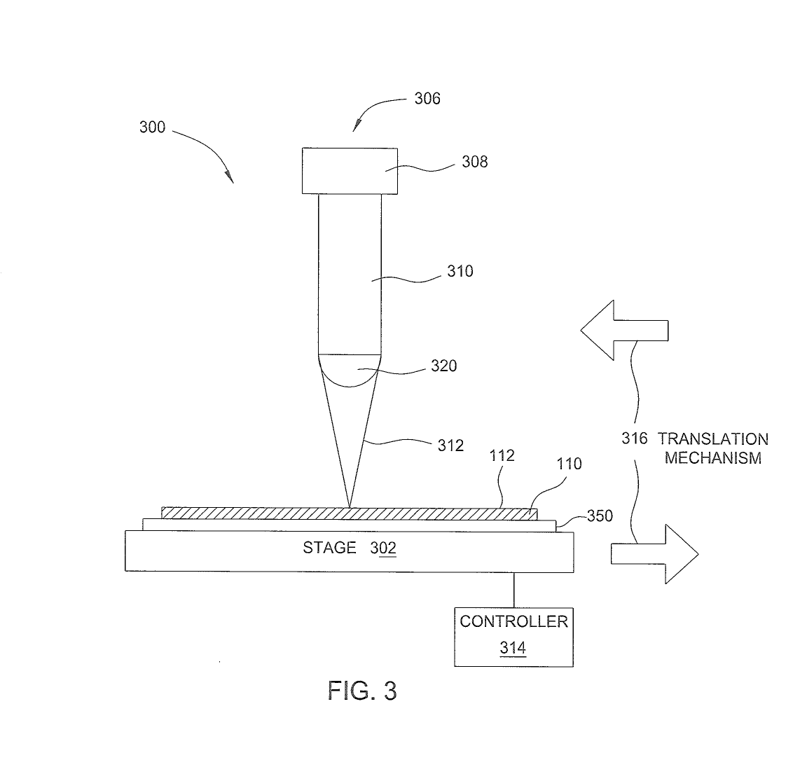

FIG. 3 depicts a laser patterning apparatus 300 that may be used to remove film materials from a material layer to form openings in the material layer disposed on a substrate. In one embodiment, the laser patterning apparatus 300 comprises a laser module 306, a stage 302 configured to support a substrate 350 during processing, and a translation mechanism 316 configured to control the movement of the stage 302. The laser module 306 comprises a laser radiation source 308 and a focusing optical module 310 disposed between the laser radiation source 308 and the stage 302.

In one embodiment, the laser radiation source 308 may be a light source made from Nd:YAG, Nd:YVO₄, crystalline disk, fiber-Diode and other sources that can provide and emit a continuous wave of radiation at a wavelength between about 180 nm and about 2000 nm, such as about 355 nm. In another embodiment, the laser radiation source 308 may include multiple laser diodes, each of which produces uniform and spatially coherent light at the same wavelength. In yet another embodiment, the power of the laser diode/s is in the range of about 10 Watts to 200 Watts.

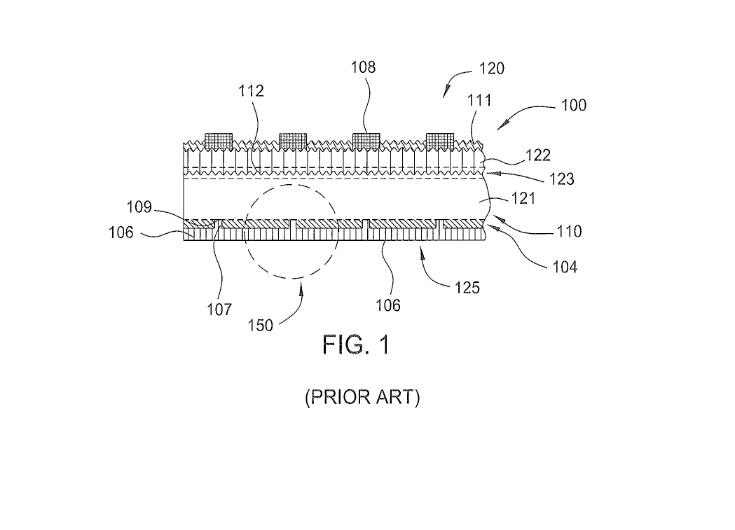

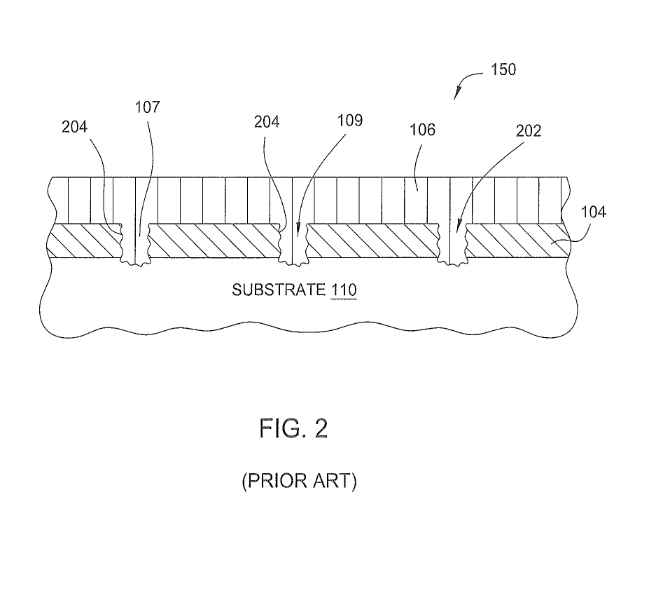

The radiation beam from the focusing optical module 310 is then focused by at least one lens 320 into a line of radiation 312 directed at a material layer, such as the passivation layer 352 similar to the passivation layer 104 depicted in FIG. 1, disposed on the substrate 350. The radiation 312 is controlled to be scanned along on a surface of a material layer disposed on the substrate 350, such as the passivation layer 352 similar to the passivation layer 104 depicted in FIG. 1, to remove a portion of the passivation layer 352 to form openings therein. In one embodiment, the radiation 312 may scan around the surface of the passivation layer 352 disposed on the substrate 350 as many times as needed until the openings are formed in the passivation layer 352 as desired.

Lens 320 may be any suitable lens, or series of lenses, capable of focusing radiation into a line or spot. In one embodiment, lens 320 is a cylindrical lens. Alternatively, lens 320 may be one or more concave lenses, convex lenses, plane mirrors, concave mirrors, convex mirrors, refractive lenses, diffractive lenses, Fresnel lenses, gradient index lenses, or the like.

The laser patterning apparatus 300 may include the translation mechanism 316 configured to translate the stage 302 and the line of radiation 312 relative to one another. In one embodiment, the translation mechanism 316 is coupled to the stage 302 that is adapted to move the stage 302 relative to the laser radiation source 308 and/or the focusing optical module 310. In another embodiment, the translation mechanism 316 is coupled to the laser radiation source 308 and/or the focusing optical module 310 to move the laser radiation source 308, the focusing optical module 310, and/or an actuated mirror (not shown) to cause the beam of energy to move relative to the substrate 350 that is disposed on the stage 302. In yet another embodiment, the translation mechanism 316 moves both the laser radiation source 308 and/or the focusing optical module 310, and the stage 302. Any suitable translation mechanism may be used, such as a conveyor system, rack and pinion system, or an x/y actuator, a robot, or other suitable mechanical or electro-mechanical mechanism. Alternatively, the stage 302 may be configured to be stationary, while a plurality of galvanometric heads (not shown) may be disposed around the substrate edge to direct radiation from the laser radiation source 308 to the substrate edge as needed.

The translation mechanism 316 may be coupled to a controller 314 to control the scan speed at which the stage 302 and the line of radiation 312 move relative to one another. In general, the stage 302 and the line of radiation 312 are moved relative to one another so that the delivered energy translates to desired one regions of the passivation layer 352 formed on the substrate 350 so that other regions of the passivation layer 352 formed on the substrate 350 are not exposed to the radiation and consequently not damaged. In one embodiment, the translation mechanism 316 moves at a constant speed. In another embodiment, the translation of the stage 302 and movement of the line of radiation 312 follow different paths that are controlled by the controller 314.

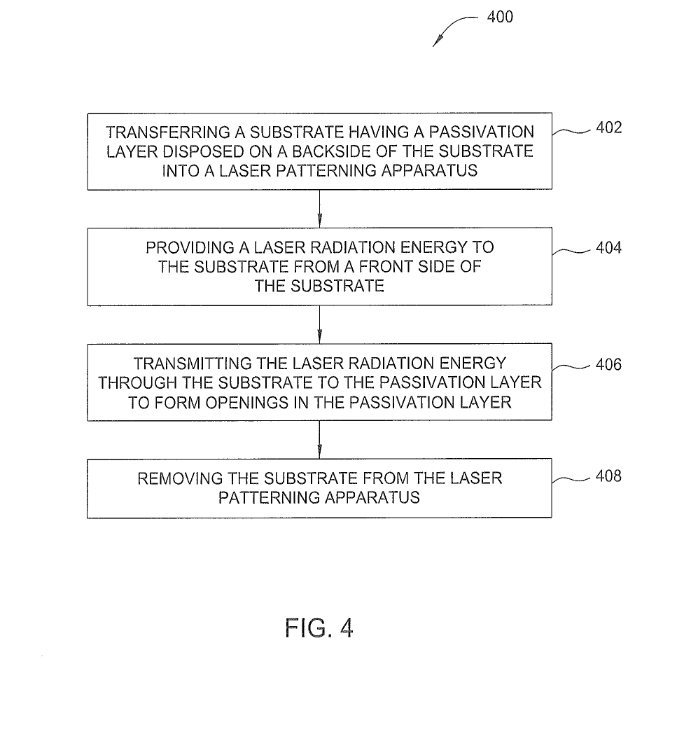

FIG. 4 depicts a flow diagram of a process 400 for performing a laser patterning process on a passivation layer disposed on a back surface of a substrate for forming a solar cell device according to embodiments of the invention. The laser patterning process may be performed by a laser patterning apparatus, such as the laser patterning apparatus 300 described above with referenced to FIG. 3, by providing a laser radiation with a desired energy level from a front surface of a substrate to a passivation layer disposed on a back surface of the substrate. It is contemplated that the process 400 may be adapted to be performed in any other suitable processing apparatus, including those available from other manufacturers, to form openings in a passivation layer disposed on a substrate. It should be noted that the number and sequence of steps illustrated in FIG. 4 are not intended to limiting as to the scope of the invention described herein, since one or more steps can be added, deleted and/or reordered were appropriate without deviating from the basic scope of the invention described herein.

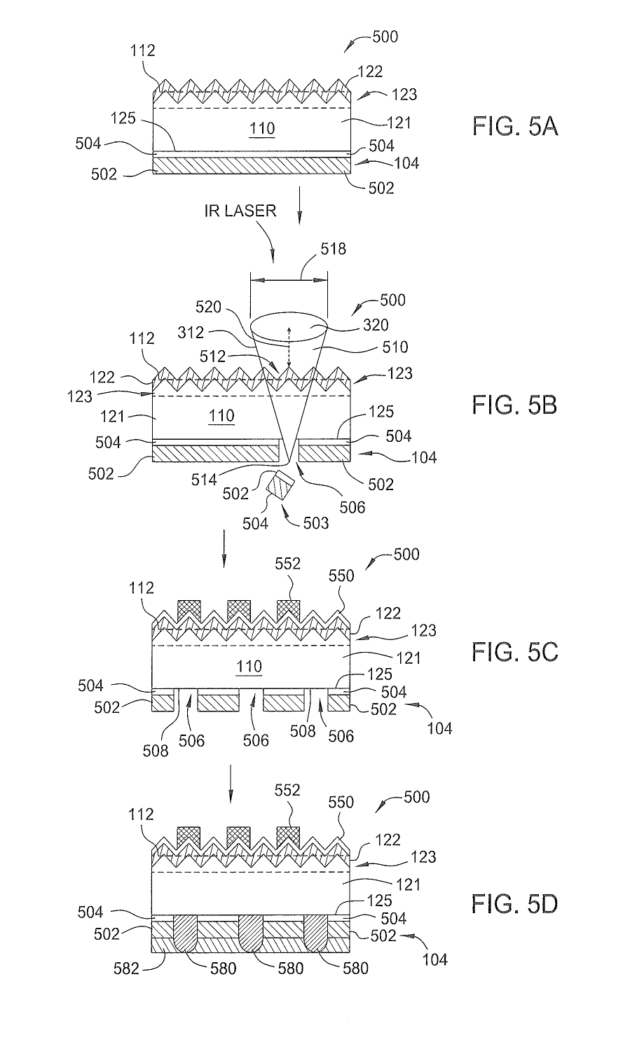

The process 400 begins at step 402 by transferring a substrate, such as the substrate 110 having the passivation layer 104 disposed on the back side 125 of the substrate 110, into a laser patterning apparatus, such as the laser patterning apparatus 300 depicted in FIG. 3, to form openings in the passivation layer 104, as depicted in FIG. 5A.

As briefly discussed above, the substrate 110 may be a crystalline silicon type solar cell substrate 110 having the textured surface 112. The substrate 110 includes the p-type base region 121, the n-type emitter 122, and the p-n junction region 123 disposed therebetween. The n-type emitter 122 may be formed by doping a deposited semiconductor layer with certain types of elements (e.g., phosphorus (P), arsenic (As), or antimony (Sb)) in order to increase the number of negative charge carriers, i.e., electrons. In one embodiment, the n-type emitter 122 is formed by use of an amorphous, microcrystalline, nanocrystalline, or polycrystalline CVD deposition process that contains a dopant gas, such as a phosphorus containing gas (e.g., PH₃). The passivation layer 104 is disposed on the p-type base region 121 on the back surface 125 of the solar cell 500. The passivation layer 104 may be a dielectric layer providing good interface properties that reduce the recombination of the electrons and holes, drives and/or diffuses electrons and charge carriers back to the junction region 123. In one embodiment, the passivation layer 104 may be fabricated from a dielectric material selected from a group consisting of silicon nitride (Si₃N₄), silicon nitride hydride (SiₓN_{y}:H), silicon oxide, silicon oxynitride, a composite film of silicon oxide and silicon nitride, a composite film of silicon nitride and aluminum oxide layer, an aluminum oxide layer, a tantalum oxide layer, a titanium oxide layer, or any other suitable materials. In an exemplary embodiment, the passivation layer 104 is a composite layer having a first dielectric layer 502 disposed on a second dielectric layer 504. In one embodiment, the first dielectric layer 502 is a silicon nitride layer and the second dielectric layer 504 is an aluminum oxide layer (Al₂O₃) disposed on the back surface 125 of the substrate 110. The silicon nitride layer 502 and the aluminum oxide layer (Al₂O₃) 504 may be formed by any suitable deposition techniques, such as atomic layer deposition (ALD) process, plasma enhanced chemical vapor deposition (PECVD) process, metal-organic chemical vapor deposition (MOCVD), sputter process or the like. In an exemplary embodiment, the aluminum oxide layer (Al₂O₃) 504 is formed by an ALD process having a thickness between about 5 nm and about 100 nm and the silicon nitride layer 502 may be formed by a CVD process having a thickness between about 50 nm and about 400 nm. The passivation layer 104 is formed on the back surface 125 of the substrate 110 ready to form openings therein by the process 400 that later allows fingers of the back metal contact to be filled. The detail of the process 400 with regard to forming openings in the passivation layer 352 from the front surface 112 of the substrate 110 will be described below.

At step 404, a laser patterning process is performed on the passivation layer 104 disposed the back side 125 of the substrate 110 on the stage 302 disposed in the apparatus 300, as shown in the exemplary embodiment depicted in FIG. 3. The radiation beam may be focused by the len 320 forming the line of radiation 312 aiming at the desired spot 514 in the passivation layer 104 so as to form openings 506 in the passivation layer 104. Unlike the conventional practice that requires the substrate to be flipped over to expose the passivation layer 104 disposed on the back surface 125 to the laser radiation for the laser patterning process, the substrate 110 is proceed with the front surface 112 of the substrate 110 facing up towards the laser module 306 when disposed on the stage 302. The line of radiation 312 is focused on the predetermined spot 514 in the passivation layer 104 so as to push (e.g., lift off) a stack film 503 including the first dielectric layer 502 and the second dielectric layer 504 out from the passivation layer 104, forming the openings 506 in the passivation layer 104 with a desired dimension.

In one embodiment, an energy level of the laser radiation 312 is selected so that the laser radiation may pass from the front surface 120 through the body of the substrate 110 to the passivation layer 104 without damaging the crystalline structure thereof. Additionally, by utilizing the laser radiation at a controlled energy level, the controlled laser energy may provide a mild thermal energy to a region 512 of the n-type emitter 122 formed on the front side 112 of the substrate 110 when passing therethrough without adversely damaging the film structure thereof. It is noted that the region 512 of the n-type emitter 122 is located at the region 512 corresponding to the spot 514 in the passivation layer 114 on a same vertical plane where the film stack 503 is intended to be removed from the substrate 110 disposed oppositely on the back side 125 of the substrate 110.

It is believed that single crystalline silicon, e.g., the material utilized to form the solar cell substrate, has low absorption to the laser radiation at long wavelength of infrared light. As such, by utilizing this particular characteristic of silicon, when an infrared light with a relatively longer wavelength, such as greater than 600 nm, transmits through a substrate made from silicon, the infrared light may mostly transmit through the single crystalline silicon substrate with minimum absorption by the silicon substrate. Accordingly, the energy of the infrared light may mostly carry and pass through the body of the silicon substrate reaching down to the desired spot 514 where the focusing len 320 is configured to focus on. As such, the energy of the infrared light reaches down to the spot 514 may still maintain a high energy level as generated with minimum absorption by the substrate passed therethrough. Furthermore, as the energy of the infrared light passing through the substrate may only have minimum absorption by the substrate, the crystalline structure and lattice characteristic of the substrate may not be damaged. In one example, the substrate 110 utilized herein is a single crystalline silicon material. However, as the laser energy passing through the substrate 110 may inevitably generate some thermal energy, the thermal energy as generated therein may only provide mild heat energy to the substrate surface, such as the region 512 of the n-type emitter 122, so as to slightly and gently anneal the region 512 of the n-type emitter 122 which activate the dopants doped therein without undesirably damaging the film properties. In one embodiment, the substrate 110 may have a thickness between about 50 μm and about 220 μm.

Furthermore, a width 518 of the len 320 may be selected to focus the radiation on the desired spot 514 so as to remove the film stack 503 from the back side 125 of the substrate 110. It is noted that the width 518, e.g., the dimension, of the lens 320 may be varied to generate different flurence to the region 512 passing through the n-type emitter 122, as well as the energy level of the laser radiation penetrating to the spot 514 in the passivation layer 114. The varied width 518 of the lens 320 may assist controlling the thermal energy as well as energy level of the laser radiation created to both the region 512 of the n-type emitter region 122 and the spot 514 where the film stack 503 is intended to be removed. In one embodiment, the len width 518 is controlled at between about 1 mm and about 8 mm.

At step 406, the laser energy is transmitted through the substrate 110 to the passivation layer 104 to form openings 506 therein, as shown in FIG. 50. In one embodiment, the laser patterning process is performed by applying a series of laser pulses through the substrate 110 to the predetermined spots on the passivation layer 104 to form the openings 506 in the passivation layer 104. The laser pulses may be applied continuously or intermittently to the substrate 110 as need.

The radiation comprising the bursts of laser pulses may have a wavelength greater than 600 nm, such as greater than 800 nm, for example between about 1000 nm and about 2000 nm. Each pulse is focused or imaged to spot at desired regions of the passivation layer 104 to form openings 506 therein. Each pulse is focused so that the first spot is at the start position of an opening to be formed in the passivation layer 104. Each opening as formed in the passivation layer 104 may have equal distance to each other. Alternatively, each opening 506 may be configured to have different distances from one another, or may be spaced/located in any manner as needed.

In one embodiment, the spot size of the laser pulse formed in the passivation layer 104 is controlled at between about 15 μm and about 150 μm, such as about 80 μm. The spot size of the laser pulse may be configured in a manner to form openings 506 in the passivation layer 104 with desired dimension and geometries. In one embodiment, a spot size of a laser pulse about 120 μm may form an opening 506 in the passivation layer 104 with a diameter about 90 μm.

The laser pulse may have energy density (e.g., fluence) between about 200 microJoules per square centimeter (mJ/cm²) and about 1000 microJoules per square centimeter (mJ/cm²), such as about 500 microJoules per square centimeter (mJ/cm²) at a frequency between about 30 kHz and about 2 MHz. Each laser pulse length is configured to have a duration of about 10 picoseconds up to 10 nanoseconds. A single laser pulse is used to form the openings 506 in the passivation layer 104 exposing the underlying substrate 110. After a first opening is formed in a first position defined in the passivation layer 104, a second opening is then consecutively formed by moving the laser pulse to direct to a second location where the second opening desired to be formed in the passivation layer 104. The laser patterning process is continued until a desired number of the openings 506 are formed in the passivation layer 104. In one embodiment, the total opening areas created by the openings 506 formed in the passivation layer 104 is about 5 percent of the area of substantially the entire passivation layer 104.

Furthermore, multiple wavelengths of the laser energy may also be utilized so as to enhance the efficiency for both the passivation layer removal process and the front side emitter region anneal process. As discussed above, different wavelengths of the laser energy may have different absorption and transmittance to the substrate, as well as to the film layers disposed thereon. Accordingly, by utilizing laser energy that may provide multiple wavelengths during the laser patterning process, the efficiency of both the passivation layer removal process and the front side emitter region anneal process may be improved. In one embodiment, a first wavelength in the range of between about 1000 nm and about 2000 nm may be utilized to mainly remove passivation layer disposed on the back side of the substrate. Subsequently, a second wavelength in the range of between about 266 nm and about 532 nm may be utilized to gently provide thermal energy to the front side emitter region anneal process. It is noted that the order and the wavelength range may be reversed or varied as needed for different process arrangement and requirements. It is noted that a single pulse for each wavelength may be utilized for this particular embodiment.

At step 408, after the laser patterning process, the substrate 110 can then be removed from the laser patterning apparatus. Subsequently, a plurality of fingers 580 and a back metal contact 582 can then be formed and filled in the openings 506 formed in the passivation layer 104, as shown in FIG. 5D. The plurality of fingers 107 and the back metal contact 106 may be formed within the passivation layer 580 that are electrically connected to the back metal contact 582 to facilitate electrical flow between the back contact 582 and the p-type base region 121. In one embodiment, the back contact 582 disposed on the back surface 125 of the substrate 110 using a screen printing process performed in a screen printing tool, which is available from Baccini S.p.A, a subsidiary of Applied Materials, Inc. In one embodiment, the back contact 582 is heated in an oven to cause the deposited material to densify and form a desired electrical contact with the substrate back 125. It is noted other processes, such as a cleaning process, a rinse process, or other suitable process may be performed after the densifying process at step 406, before the metal back deposition process

Thus, the present application provides methods for forming openings in a passivation layer on a back side of a solar cell. The methods advantageously form openings in a passivation layer disposed on a back side of a substrate by supplying an laser energy from a front surface of the substrate. The laser energy advantageous removes portion of the passivation layer disposed on the back side of the substrate to create a strong and robust interface while thermal annealing a region of an emitting layer disposed on a front side of the substrate. Strong and robust interface formed between the passivation layer and the back side of the substrate may assist enhancing photocurrent generated in the solar junction cell, thereby improving the overall solar cell conversion efficiency and electrical performance.

While the foregoing is directed to embodiments of the present invention, other and further embodiments of the invention may be devised without departing from the basic scope thereof, and the scope thereof is determined by the claims that follow.

1. A method of forming an opening in a passivation layer on a back surface of a solar cell substrate, comprising:
transferring a substrate having a passivation layer formed on a back surface of the substrate into a laser patterning apparatus, the substrate having a first type of doping atom on the back surface of the substrate and a second type of doping atom on a front surface of the substrate;
providing laser radiation generated by the laser patterning apparatus from a predetermined location of the front surface transmitting through the substrate to the passivation layer disposed on the back surface of the substrate; and
forming openings in the passivation layer while heating the predetermined location of the front surface of the substrate.

2. The method of claim 1, wherein the substrate comprises a p-type substrate and the first type of doping atom is boron.

3. The method of claim 1, wherein the passivation layer includes a film stack having a first dielectric layer formed on a second dielectric layer on the back surface of the substrate.

4. The method of claim 3, wherein the first dielectric layer is a silicon nitride layer and the second dielectric layer is an aluminum oxide layer.

5. The method of claim 1, wherein providing laser radiation further comprises:
providing a plurality of laser pulses at a wavelength greater than about 600 nm.

6. The method of claim 1, wherein providing laser radiation further comprises:
providing a single pulse with a duration of 10 picoseconds up to about 10 nanoseconds.

7. The method of claim 1, wherein providing laser radiation further comprises:
providing laser radiation with more than one wavelength to the substrate.

8. The method of claim 1, wherein providing laser radiation further comprises:
directing the laser radiation through a region of the front surface of the substrate; and
thermal annealing the region of the front surface of the substrate.

9. The method of claim 1, wherein providing laser radiation further comprises:
adjusting an energy level of the laser radiation transmitting through the substrate to the passivation layer.

10. The method of claim 9, wherein the energy level of the laser radiation is adjusted by a focusing length defined between the front surface of the substrate and a focusing lens disposed in the laser patterning apparatus.

11. The method of claim 1, wherein providing laser radiation comprises providing radiation at a wavelength range that has minimum absorption to the substrate.

12. The method of claim 1, wherein providing laser radiation to the passivation layer further comprises:
pulsing laser energy between about 200 microJoules per square centimeter (mJ/cm²) and about 1000 microJoules per square centimeter (mJ/cm²) to the passivation layer.

13. The method of claim 1, further comprising:
forming a back metal layer in the openings formed in the passivation layer, wherein the back metal is selected from a group consisting of aluminum (Al), silver (Ag), tin (Sn), cobalt (Co), nickel (Ni), zinc (Zn), lead (Pb), tungsten (W), titanium (Ti) and/or tantalum (Ta) and nickel vanadium (NiV).

14. The method of claim 1, wherein the openings formed in the passivation layer create an opening area of about 4 percent relative to an area of the passivation layer formed on the substrate back surface.

15. A method of forming an opening in a passivation layer on a back surface of a solar cell substrate, comprising:
transferring a substrate having a passivation layer formed on a back surface of a substrate into a laser patterning apparatus, the substrate fabricated from a crystalline silicon material having a first type of doping atom on the back surface of the substrate and a second type of doping atom formed in a predetermined location on a front surface of the substrate;
providing laser radiation from the laser patterning apparatus to the passivation layer disposed on the back surface of the substrate, wherein the laser radiation is selected at a wavelength that has minimum absorption to the crystalline silicon material formed in the substrate; and
forming openings in the passivation layer while activating the second type of the doping atoms located in the predetermined location of the front surface.

16. The method of claim 15, wherein providing laser radiation further comprises:
transmitting the laser radiation from the predetermined region of the front surface passing through the substrate to the passivation layer disposed on the back surface of the substrate.

17. The method of claim 15, wherein the wavelength is greater than about 600 nm.

18. The method of claim 15, wherein providing the laser radiation further comprises:
thermal annealing the region of the front surface.

19. The method of claim 15, wherein the passivation layer includes a film stack having a first dielectric layer formed on a second dielectric layer on the back surface of the substrate, wherein the first dielectric layer is a silicon nitride layer and the second dielectric layer is an aluminum oxide layer.

20. The method of claim 15, wherein providing laser radiation further comprises:
adjusting an energy level of the laser radiation transmitting through the substrate to the passivation layer, wherein the energy level of the laser radiation is adjusted by a focusing length defined between the front surface of the substrate and a focusing len disposed in the laser patterning apparatus.

21. A method of forming an opening in a passivation layer on a back surface of a solar cell substrate, comprising:
transferring a substrate having a passivation layer formed on a back surface of a substrate into a laser patterning apparatus, the substrate fabricating from a crystalline silicon material having a first type of doping atom on the back surface of the substrate and a second type of doping atom on a front surface of the substrate;
providing laser radiation to the passivation layer disposed on the back surface of the substrate from the front surface of the substrate; and
simultaneously forming openings in the passivation layer while thermal annealing a region of the front surface of the substrate to activate the second type of doping atom where the laser radiation is passing therethrough.
